(19) United States
(12) Patent Application Publication
(10) Pub. No.: US 2020/0331801 A1
(43) Pub. Date: Oct. 22, 2020

(54) METHOD FOR HARDENING AN ANTI-REFLECTION TREATMENT DEPOSITED ON A TRANSPARENT SUBSTRATE AND TRANSPARENT SUBSTRATE COMPRISING A HARDENED ANTI-REFLECTION TREATMENT

(71) Applicant: Comadur SA, Le Locle (CH)

(72) Inventors: Alexis BOULMAY, Morteau (FR); Julien MEIER, Neuchatel (CH); Pierry VUILLE, Les Emibois (CH)

(73) Assignee: Comadur SA, Le Locle (CH)

(21) Appl. No.: 16/959,267

(22) PCT Filed: Sep. 19, 2019
(86) PCT No.: PCT/EP2019/075256

§ 371 Date: Jun. 30, 2020

(30) Foreign Application Priority Data
Oct. 10, 2018 (EP) 18199708.1

(51) Int. Cl. C03C 23/00; G02B 1/14; G02B 1/12; G02B 1/113; C23C 14/24; C23C 14/48; C23C 14/10; C03C 17/245; C03C 17/22; G04B 39/00

(52) U.S. Cl. CPC C03C 23/0055; C03C 2218/32; G02B 1/12; G02B 1/113; C23C 14/24; C23C 14/48; C23C 14/10; C03C 17/245; C03C 17/22; G04B 39/006; C03C 2217/213; C03C 2217/285; C03C 2217/732; C03C 2218/151; G02B 1/14

(57) ABSTRACT

A method hardens an anti-reflection treatment deposited on a transparent substrate that includes a top surface and a bottom surface which extends remotely from the top surface. The anti-reflection treatment includes depositing at least one anti-reflection layer of at least one material on at least one of the top and bottom surfaces of the transparent substrate, bombarding the at least one top or bottom surface on which the at least one anti-reflection layer has been deposited using a singly-charged and/or multi-charged ion beam produced by a singly-charged and/or multi-charged ECR electron cyclotron resonance ion source. The method produces a transparent substrate having undergone an anti-reflection treatment such that at least one of the top and bottom surfaces of the transparent substrate is coated with at least one anti-reflection layer of at least one material, whereby ions are implanted in the at least one anti-reflection layer.

### TECHNICAL FIELD OF THE INVENTION

The present invention relates to a method for hardening an anti-reflection treatment deposited on a transparent substrate. More particularly, the present invention relates to a method for hardening an anti-reflection treatment deposited by vacuum evaporation on a sapphire substrate. The present invention further relates to a transparent substrate coated with a hardened anti-reflection treatment.

### BACKGROUND OF THE INVENTION

The first anti-reflection treatments applied to watch crystals date from a few decades ago. The purpose of these anti-reflection treatments is to improve the legibility of a watch dial when viewed by the individual wearing the watch through the crystal thus treated. More specifically, a ray of light originating from the exterior and passing through the watch crystal is reflected a first time at the interface between the air and the material from which the crystal is made, and is reflected a second time when it emerges from the crystal and is propagated towards the dial. After reflecting on the dial, the light ray passes through the crystal again and undergoes another double reflection.

It is understood that these multiple reflection phenomena significantly hinder the legibility of the information displayed by the dial of a watch. This is why efforts were made very early on to provide watch crystals with anti-reflection treatments. The interest in this technology further increased when sapphire watch crystals first appeared. More specifically, as a result of the relatively high optical refractive index thereof, a sapphire glass re-emits—compared to mineral glass—almost double the light, thus resulting in significant reflection of the light at the interface thereof with the air.

A watch crystal comprises a top surface, located on the side nearest the individual wearing the watch, and a bottom surface located on the side nearest the dial of the watch. The anti-reflection treatment of a watch crystal consists of coating at least one of the top and bottom surfaces of the crystal with at least one layer of at least one material, the optical refractive index thereof lying in the range between that of air and that of the material from which the watch crystal is made.

The present invention particularly concerns watch crystals, however is not limited exclusively thereto. More generally, the present invention concerns all types of transparent substrate, the incident light reflectivity properties thereof being sought to be reduced. A transparent substrate is understood herein to be a substrate that allows light to pass and clearly shows the objects located behind it. The present invention also particularly concerns watch crystals made of sapphire, but is not limited exclusively thereto. However, the present invention further concerns substrates made of any transparent material such as mineral glass, organic glass or plastic materials.

An anti-reflection treatment is understood herein to be a method that aims to modify the optical reflection properties of a transparent substrate, in particular a watch crystal, with the purpose of reducing the reflectivity of such a transparent substrate relative to an identical transparent substrate not having undergone treatment.

The anti-reflection treatment methods concerned herein consist of depositing, under vacuum, at least one layer of at least one material on one of the top and bottom faces of a transparent substrate. The anti-reflection treatment methods conducted under vacuum concerned herein include physical vapour deposition or PVD, chemical vapour deposition or CVD, plasma-enhanced chemical vapour deposition or PECVD, or even atomic layer deposition techniques or ALD.

As understood from the above, the anti-reflection treatment techniques concerned herein consist of depositing, under vacuum, one or more layers of at least one material on at least one of the top and bottom faces of a transparent substrate in order to reduce the reflectivity of such a transparent substrate relative to an incident light ray. A transparent substrate is understood herein to particularly mean watch crystals, optical devices, in particular ophthalmic devices such as spectacle lenses, and more generally any transparent device, the reflectivity thereof being sought to be reduced for technical and/or aesthetic reasons.

The anti-reflection layers have the advantage of reducing the light reflectivity of the transparent substrates on which they are deposited. Depending on the thickness and the materials from which they are made, these anti-reflection layers can also modify the colour of the transparent substrates.

However, the anti-reflection layers have the drawback of being less hard and thus of being less resistant to scratches than the substrates on which they are deposited. This is particularly true in the case of such anti-reflection layers deposited on a sapphire substrate, which material it is known only a diamond can scratch.

In order to overcome this problem, some watch manufacturers opt to only carry out an anti-reflection treatment on the bottom surface of their crystals, i.e. on the surface facing the dial, which is not entirely satisfactory.

### SUMMARY OF THE INVENTION

There was therefore a commercial need for anti-reflection layers, the optical properties whereof are preserved and which are harder, and thus more resistant to the scratches and impacts which can arise during transport, handling or wearing.

For this purpose, the present invention relates to a method for hardening an anti-reflection treatment deposited on a transparent substrate, this transparent substrate comprising a top surface and a bottom surface which extends remotely from the top surface, the anti-reflection treatment comprising the step consisting of depositing at least one anti-reflection layer of at least one material on at least one of the top and bottom surfaces of the transparent substrate, the hardening method further comprising the step consisting of bombarding the at least one top or bottom surface on which the anti-reflection layer has been deposited using a singly-charged or multi-charged ion beam produced by a singly-charged or multi-charged ion source.

The singly-charged or multi-charged ion source is of the electron cyclotron resonance type or ECR.

The term “singly-charged ions” is understood herein to mean ions having a degree of ionisation equal to 1. The term “multi-charged ions” is understood herein to mean ions having a degree of ionisation greater than 1. The ion beam produced by the ion source can be formed of ions that all have the same degree of ionisation, or be formed of a mixture of ions having at least two different degrees of ionisation.

According to preferred embodiments of the invention:

the transparent substrate is made of sapphire;

the transparent substrate made of sapphire is a watch crystal;

the material to be ionised is selected from the group consisting of carbon (C), oxygen (0), nitrogen (N), argon (Ar), helium (He), xenon (Xe) and neon (Ne);

the singly-charged or multi-charged ions are accelerated under a voltage that lies in the range 30 kV to 50 kV;

the dose of implanted ions lies in the range 0.1-10¹⁶ions/cm² to 2-10¹⁶ions/cm²;

the duration of the ion implantation process does not exceed 5 seconds;

the one or more anti-reflection layers are made using silicon oxide (SiO₂) or magnesium fluoride (MgF₂);

the thickness of the anti-reflection layers does not exceed 150 nm;

the anti-reflection treatment resulting from the deposition of one or more anti-reflection layers has an optical refractive index that does not exceed 1.55;

before deposition of the at least one anti-reflection layer, the top and/or bottom surface of the transparent substrate undergoes ion bombardment;

at least one additional anti-reflection layer is deposited on the top and/or bottom surface that underwent ion bombardment after anti-reflection treatment.

Thanks to these features, the present invention provides a method which allows the anti-reflection layers deposited on a transparent substrate such as a sapphire watch crystal to be hardened, and thus made more resistant to the scratches and impacts to which they could be subjected during transport, handling or wearing.

More specifically, all of the mechanical characterisation tests (scratch resistance and impact resistance) provided for by the horological standard NIHS 61-30 show a clear improvement in the mechanical properties of the anti-reflection treatments in the case where these anti-reflection treatments have undergone ion bombardment according to the invention. Moreover, it has been noted with satisfaction that the optical properties of the anti-reflection layers were in no way affected by the ion implantation method according to the invention.

As a result, those horological manufacturers who, on the grounds of the anti-reflection layers having a mechanical strength that is considered to be insufficient against scratches and impacts, have until now only provided their watch crystals with an anti-reflection treatment on the bottom surface of these crystals facing the dial, can now consider also carrying out an anti-reflection treatment on the top surface of the watch crystals facing the individual wearing the watch, which substantially improves the legibility of the information displayed by the watch dials when viewed through the crystals.

Another object of the invention relates to a transparent substrate bearing an anti-reflection treatment, this transparent substrate comprising a top surface and a bottom surface which extends remotely from the top surface, at least one of the top and bottom surfaces of the transparent substrate being coated with at least one anti-reflection layer of at least one material, whereby ions are implanted in the at least one anti-reflection layer.

### BRIEF DESCRIPTION OF THE FIGURES

Other features and advantages of this invention will appear more clearly upon reading the following detailed description of one example of implementation of the method according to the invention, said example being provided for illustrative purposes only and not intended to limit the scope of the invention, with reference to the accompanying drawing, wherein:

FIG. 1 is a diagrammatic view of a singly-charged or multi-charged ion source of the ECR electron cyclotron resonance type;

FIG. 2A is an overhead view of a flat sapphire watch crystal having undergone an anti-reflection treatment and having been subjected to a scratch resistance test;

FIG. 2B is an overhead view, at the same scale, of the same flat sapphire watch crystal having undergone the same anti-reflection treatment as that shown in FIG. 2A, then having been subjected to ion bombardment in accordance with the present invention, the scratch resistance of this watch crystal having then been tested, and

FIG. 3 shows the difference in hardness between an anti-reflection treatment deposited on a sapphire watch crystal that has not undergone ion bombardment, and the same anti-reflection treatment on an identical sapphire watch crystal having undergone ion implantation by bombardment.

### DETAILED DESCRIPTION OF ONE EMBODIMENT OF THE INVENTION

The present invention was drawn from the general inventive idea consisting of implanting ions by bombardment in an anti-reflection treatment deposited on at least one of the top and bottom surfaces of a transparent substrate such as a sapphire watch crystal. More specifically, after ion bombardment, the anti-reflection treatment, formed by one or more anti-reflection layers, was seen to have a substantially improved mechanical strength against the scratches and impacts that could arise during handling, transport or wearing. Moreover, the optical properties of the anti-reflection layers was in no way affected by the ion bombardment in accordance with the invention, such that some horological manufacturers who, until now, have hesitated to coat the top surface of their watch crystals with an anti-reflection treatment due to the mechanical strength properties thereof which were considered insufficient, can now subject their watch crystals to an anti-reflection treatment on both the top and bottom surfaces, such that the spurious reflection phenomena are substantially reduced and the legibility of the information displayed by the dial of the watched viewed through the crystal is vastly improved. These results are relatively unexpected given the low thickness of the anti-reflection layers, which does not exceed 150 nm and which is often equal to about several tens of nanometres. More specifically, instead of reinforcing the mechanical strength of the anti-reflection layers, it was feared that the ion bombardment would weaken same and alter the optical properties thereof. This however is not the case. In fact, the contrary was observed.

The present invention will now be described in connection to a sapphire watch crystal. It goes without saying that this example is provided for illustrative purposes only and is not intended to limit the invention, and that the present invention can be applied in an identical manner to all types of transparent substrate, for example a substrate made of mineral glass, organic glass or even plastic material, receiving an anti-reflection treatment such as spectacle lenses or lenses of optical devices, for example cameras.

Similarly, the present invention will now be described in connection to a singly-charged or multi-charged ion source of the electron cyclotron resonance (ECR) type.

An ECR ion source uses electron cyclotron resonance to create a plasma. A volume of low-pressure gas is ionised by microwaves injected at a frequency corresponding to the electron cyclotron resonance defined by a magnetic field applied to a region located inside the volume of gas to be ionised. The microwaves heat the free electrons present in the volume of gas to be ionised. Under the effect of thermal agitation, these free electrons collide with the atoms or molecules of gas and cause the ionisation thereof. The ions produced correspond to the type of gas used. This gas can be pure or a compound. It can also be a vapour produced from a solid or liquid material. The ECR ion source is capable of producing singly-charged ions, i.e. ions with a degree of ionisation equal to 1, or multi-charged ions, i.e. ions with a degree of ionisation greater than 1.

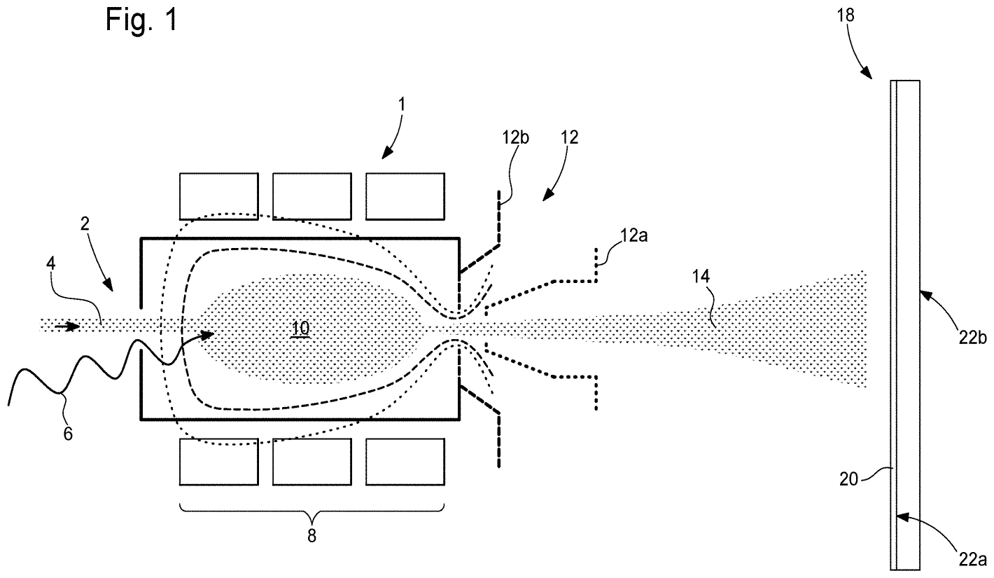

An ion source of the ECR electron cyclotron resonance type is diagrammatically shown in FIG. 1 accompanying the present patent application. Denoted as a whole by the general reference numeral 1, an ECR ion source comprises an injection stage 2, into which a volume 4 of a gas to be ionised and a microwave 6 are injected, a magnetic confinement stage 8, wherein a plasma 10 is created, and an extraction stage 12, which allows the ions of the plasma 10 to be extracted and accelerated using an anode 12a and a cathode 12b between which a high voltage is applied. An ion beam 14 produced at the output of the ECR ion source 1 strikes a surface of a transparent substrate to be treated, in this case a watch crystal 18, and penetrates more or less deeply within the anti-reflection treatment 20 structured on at least one of the top surface 22a and bottom surface 22b of the watch crystal 18 to be treated.

The gas to be ionised can be chosen from carbon (C) obtained, for example, from carbon dioxide (CO₂) or from methane (CH₄), oxygen (O), argon (Ar), nitrogen (N), helium (He), xenon (Xe) or neon (Ne). The ions can be of the singly-charged type, i.e. the degree of ionisation thereof is equal to +1, or of the multi-charged type, i.e. the degree of ionisation thereof is greater than +1. The ion beam produced by the ECR ion source 1 can be formed of ions that all have the same degree of ionisation, or be formed of a mixture of ions having at least two different degrees of ionisation.

The singly-charged or multi-charged ions are accelerated under a voltage that lies in the range 30 kV to 50 kV, the dose of ions to be implanted lies in the range 0.1-10¹⁶ ions/cm² to 2-10¹⁶ ions/cm² and the duration of ion implantation does not exceed 5 seconds.

The one or more anti-reflection layers are made using silica (SiO₂) or magnesium fluoride (MgF₂) for example. Silica layers can be combined with magnesium fluoride layers. The thickness of these layers considered individually does not conventionally exceed 150 nm. Other materials such as titanium, tantalum, zirconium, silicon and aluminium oxides, as well as silicon nitride can also be used to produce the anti-reflection layers. These anti-reflection layers are deposited by vacuum evaporation. The vacuum deposition techniques that can be considered include physical vapour deposition or PVD, chemical vapour deposition or CVD, plasma-enhanced chemical vapour deposition or PECVD, or even atomic layer deposition techniques or ALD.

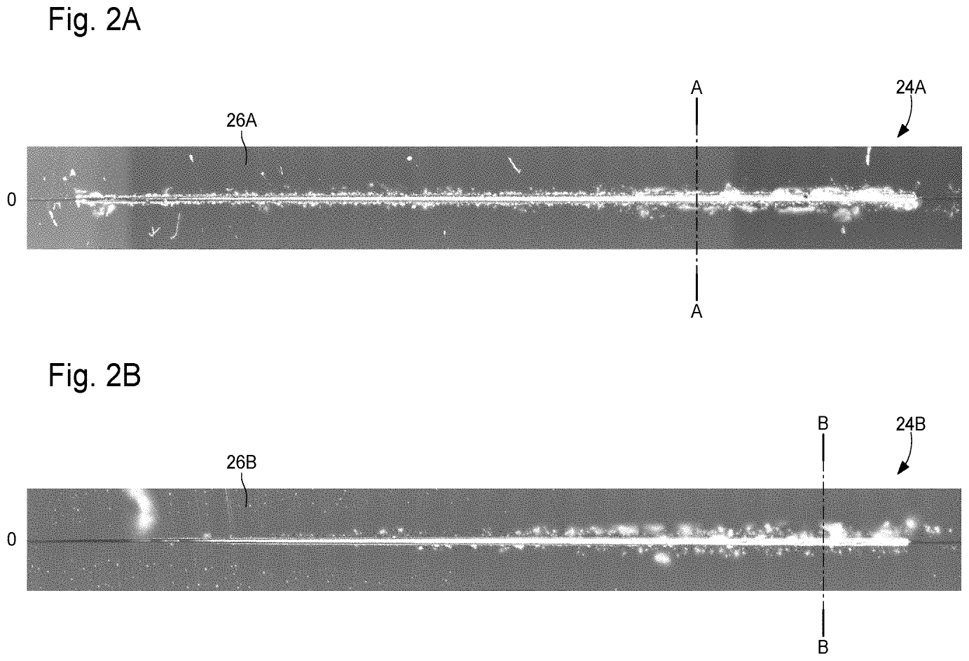

FIG. 2A is an overhead view of a flat watch crystal 24A made of sapphire having undergone an anti-reflection treatment 26A formed by a layer of magnesium fluoride MgF₂ measuring 90 μm in thickness and having been subjected to a scratch resistance test. This test consists of scratching the anti-reflection treatment 26A over a distance of 0.5 mm using a diamond point having a spheroconic geometrical configuration with a radius of 5 μm. The diamond point is displaced at a speed of 1 mm/min. It is applied at the origin O with a force substantially equal to zero, this force increasing in a linear manner by a speed of 401.88 mN/min to reach 200 mN at the end of the 0.5 mm distance. It should be noted that the diamond point is displaced from left to right in FIG. 2A.

In FIG. 2A, the place at which the sapphire of the flat watch crystal 24A is bared is designated by the line A-A. In FIG. 2B, the same flat watch crystal 24B made of sapphire is shown, to the same scale, having undergone the same anti-reflection treatment 26B as the flat sapphire watch crystal 24A in FIG. 2A. However, the flat sapphire watch crystal 24B in FIG. 2B was subjected, after the anti-reflection treatment, to ion implantation by bombardment in accordance with the invention. The characteristics of the ion implantation treatment to which the layer of magnesium fluoride MgF₂ measuring 90 μm in thickness was subjected are as follows:
type of ions implanted: nitrogen
ion acceleration voltage: 40 kV;
ion implantation dose: in the range 0.1-10¹⁶ ions/cm² to 0.25-10¹⁶ ions/cm²;
intensity of the ion beam: 6 mA;
vacuum conditions: 4-10⁻⁶ mbar;
penetration depth of the ions in the magnesium fluoride MgF₂ layer: about 50 nm.

Given that the experimental conditions for measuring the scratch resistance of the flat sapphire watch crystals 24A and 24B of FIG. 2A and 2B are identical, the place at which the sapphire of the flat watch crystal 24B is bared, designated by the line B-B in FIG. 2B, is seen to occur further from the origin O than in the case shown in FIG. 2A, which means that the hardness of the anti-reflection treatment 26B is increased thanks to the ion bombardment. By comparing FIG. 2A and 2B, the scratch made by the diamond point is also seen to be narrower in FIG. 2B than in FIG. 2A, which means that the delamination phenomenon of the anti-reflection treatment 26B is less significant in the case shown in FIG. 2B, and thus that this anti-reflection treatment 26B is harder and thus more scratch-resistant than in the case shown in FIG. 2A.

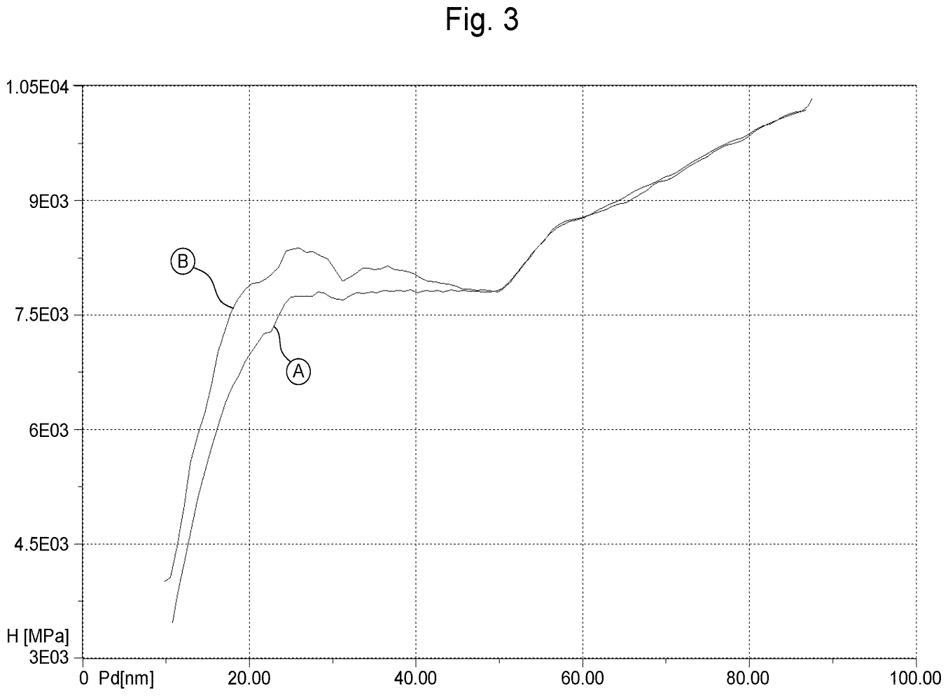

FIG. 3 shows the difference in hardness between an anti-reflection treatment deposited on a sapphire watch crystal that has not undergone ion bombardment (curve A), and the same anti-reflection treatment on an identical sapphire watch crystal having undergone ion implantation by bombardment (curve B). These hardness values obtained by measuring the elastic modulus highlight the evolution in the mechanical properties of the anti-reflection layers as a function of the depth. These hardness values were measured by the so-called instrumented indentation technique using a DMA (Dynamic Mechanical Analysis) mode, also known as Continuous Stiffness Measurement.

The chart in FIG. 3 shows, along the abscissa, the thickness of the anti-reflection treatment expressed in nanometres; the ordinate shows the hardness H, expressed in MpA, of the layers forming the anti-reflection treatment. By examining this chart, it is instantly clear that, from the surface of the anti-reflection treatment up to a depth of about 20 nm below this surface, the anti-reflection treatment having undergone ion bombardment (curve B) is approximately 20% harder than the anti-reflection treatment that did not undergo ion bombardment (curve A). At a depth that lies in the range 20 to 40 nm calculated from the surface of the anti-reflection treatment, the difference in hardness between the anti-reflection treatment having undergone ion bombardment and the anti-reflection treatment that did not undergo such an ion bombardment is still in the order of 10%, and then falls up to a depth of 50 nm. From a depth of 50 nm, the hardness curves of the anti-reflection treatment having undergone ion bombardment and of the anti-reflection treatment that did not undergo ion bombardment align and remain so up to a depth of 90 nm, which is the hardness measurement limit of the chart in FIG. 3.

It goes without saying that the present invention is not limited to the implementation of the method described above and that various simple alternatives and modifications can be considered by a person skilled in the art without leaving the scope of the invention as defined by the claims accompanying the present patent application. In particular, the present invention discloses the submission of the surface of the transparent substrate intended to undergo the anti-reflection treatment to ion bombardment before deposition of the one or more anti-reflection layers. Similarly, the present invention discloses that, after ion bombardment of the one or more anti-reflection layers, at least one additional anti-reflection layer can be deposited on the anti-reflection layers thus treated by ion implantation.

### NOMENCLATURE

1. ECR electron cyclotron resonance ion source
2. Injection stage
4. Volume of gas to be ionised
6. Microwave
8. Magnetic confinement stage
10. Plasma
12. Extraction stage
12a. Anode
12b. Cathode
14. Ion beam
18. Watch crystal
20. Anti-reflection treatment
22a. Top surface
22b. Bottom surface
24a, 24b. Flat watch crystals
26a, 26b. Anti-reflection treatments
O. Origin
A-A. Line designating the place at which the sapphire of the flat watch crystal 24A is bared
B-B. Line designating the place at which the sapphire of the flat watch crystal 24B is bared
   1-17 (canceled)

18. A method of hardening an anti-reflection treatment deposited on a transparent substrate, the transparent substrate comprising a top surface and a bottom surface which extends remotely from the top surface, the anti-reflection treatment comprising:
depositing at least one anti-reflection layer of at least one material on at least one of the top and bottom surfaces of the transparent substrate; and
bombarding the at least one top or bottom surface on which the at least one anti-reflection layer has been deposited using a singly-charged and/or multi-charged ion beam produced by a singly-charged and/or multi-charged ECR electron cyclotron resonance ion source.

19. The hardening method according to claim 18, wherein the at least one anti-reflection layer is deposited by vacuum evaporation of a material.

20. The hardening method according to claim 19, wherein the vacuum evaporation deposition technique is selected from among physical vapour deposition, chemical vapour deposition, plasma-enhanced chemical vapour deposition and atomic layer deposition.

21. The hardening method according to claim 18, wherein, before the depositing the at least one anti-reflection layer, the top and/or bottom surface to be subjected to the anti-reflection treatment undergoes ion bombardment.

22. The hardening method according to claim 21, wherein at least one additional anti-reflection layer is deposited on the anti-reflection treatment having undergone the ion bombardment.

23. The hardening method according to claim 18, wherein the ECR ion source comprises an injection stage, into which a volume of a gas to be ionised and a microwave are injected, a magnetic confinement stage, wherein a plasma is created, and an extraction stage which allows the ions of the plasma to be extracted and accelerated using an anode and a cathode between which a high voltage is applied, an ion beam produced at the output of the ECR ion source striking a surface of the transparent substrate to be treated and penetrating more or less deeply within the anti-reflection treatment structured on at least one of the top and bottom surfaces of the transparent substrate to be treated.

24. The hardening method according to claim 23, wherein the material to be ionised is selected from the group consisting of carbon, oxygen, nitrogen, argon, helium, xenon, and neon.

25. The hardening method according to claim 24, wherein the ions can be of the singly-charged type in which a degree of ionisation thereof is equal to +1, or of the multi-charged type in which the degree of ionisation thereof is greater than +1.

26. The hardening method according to claim 25, wherein the ion beam produced by the ECR ion source is formed of ions that all have the same degree of ionisation, or is formed of a mixture of ions having at least two different degrees of ionisation.

27. The hardening method according to claim 24, wherein the ions are accelerated under a voltage that lies in the range 30 kV to 50 kV.

28. The hardening method according to claim 27, wherein the dose of ions to be implanted lies in the range 0.1-10¹⁶ions/cm² to 2-10¹⁶ ions/cm².

29. The hardening method according to claim 28, wherein the duration of the ion implantation process does not exceed 5 seconds.

30. The hardening method according to claim 18, wherein the transparent substrate is made of sapphire.

31. The hardening method according to claim 30, wherein the transparent substrate is a watch crystal.

32. The hardening method according to claim 23, wherein the transparent substrate is made of sapphire.

33. The hardening method according to claim 32, wherein the transparent substrate is a watch crystal.

34. The hardening method according to claim 18, wherein the one or more anti-reflection layers are made using silica or magnesium fluoride.

35. The hardening method according to claim 34, wherein the thickness of the anti-reflection layers does not exceed 150 nm.

36. A transparent substrate having undergone an anti-reflection treatment, the transparent substrate comprising:
a top surface and a bottom surface which extends remotely from the top surface, at least one of the top and bottom surfaces of the transparent substrate being coated with at least one anti-reflection layer of at least one material, whereby ions are implanted in the at least one anti-reflection layer.
